(19) United States
(12) Patent Application Publication
(10) Pub. No.: US 2010/0163932 A1
(43) Pub. Date: Jul. 1, 2010

(54) IMAGE SENSOR AND METHOD FOR MANUFACTURING THEREOF

(76) Inventor: Sung-Ho Jun, Songpa-gu (KR)

Correspondence Address: SHERR & VAUGHN, PLLC, 620 HERNDON PARKWAY, SUITE 320, HERNDON, VA, 20170, US

(21) Appl. No.: 12/633,607

(22) Filed: Dec. 8, 2009

(30) Foreign Application Priority Data
Dec. 31, 2008 (KR) 10-2008-0137871

(51) Int. Cl. H01L 31/02; H01L 31/18; H01L 31/0248

(52) U.S. Cl. 257/225; 438/73; 438/97; 257/E31.002; 257/E31.113

(57) ABSTRACT

An image sensor may include a readout circuit formed over a first substrate made of InSb, the first substrate including a pixel part and a periphery part. A wiring and interlayer dielectric layer may be formed over the first substrate including the readout circuit. A photodiode may be formed over the interlayer dielectric layer and over the pixel part of the first substrate, and an upper electrode layer may be connected with the photodiode.

The present application claims priority under 35 U.S.C. 119 to Korean Patent Application No. 10-2008-0137871 (filed on Dec. 31, 2008), which is hereby incorporated by reference in its entirety.

### BACKGROUND

Image sensors are semiconductor devices that convert optical images into electrical signals. They are mainly divided into CCD (Charge coupled Device) image sensors and CMOS (Complementary Metal Oxide Silicon) image sensors (CIS).

CMOS image sensors produce images by sequentially detecting an electric signal of each unit pixel using a switching method. At least one photodiode and at least one MOS transistor are formed in each unit pixel. The CMOS image sensors may have a structure in which a photodiode region, which converts an input light signal into an electrical signal, and a transistor region, which processes the electrical signal, are horizontally arranged.

In the horizontal type CMOS image sensors, the photodiode and the transistor are formed horizontally adjacent to each other on a substrate. Accordingly, an additional region for forming a photodiode is required, such that a fill factor of the photosensitive region is reduced, and the resolution is limited.

### SUMMARY

Embodiments provide an image sensor and a method of manufacturing the image sensor. An image sensor according to embodiments may include: a readout circuit formed over a first substrate made of InSb, the first substrate including a pixel part and a periphery part. A wiring and interlayer dielectric layer may be formed over the first substrate including the readout circuit. A photodiode may be formed over the interlayer dielectric layer and over the pixel part of the first substrate, and an upper electrode layer may be connected with the photodiode.

A method of manufacturing an image sensor, according to embodiments, may include: forming a readout circuit and an interlayer dielectric layer including a wiring electrically connected with the readout circuit over a first substrate made of InSb, the first substrate including a pixel part and a periphery part; forming a second substrate including a photodiode; bonding the second substrate including the photodiode onto the interlayer dielectric layer; removing the second substrate such that the photodiode remains over the interlayer dielectric layer; forming an upper electrode layer connected with the photodiode and the wiring formed at the periphery region; and forming a passivation layer over the upper electrode layer.

### DRAWINGS

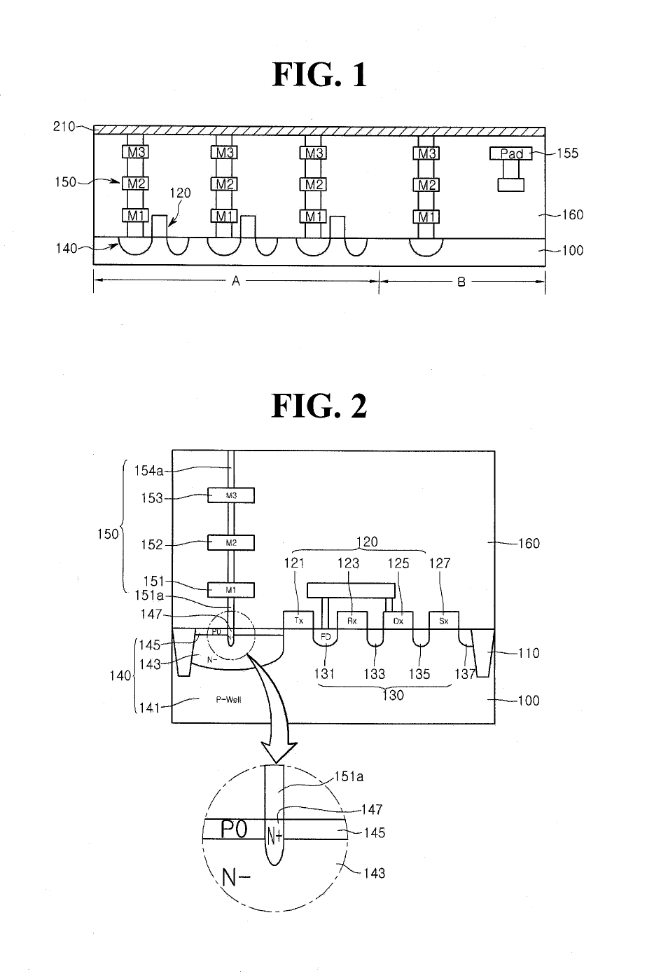

Example FIGS. 1 to 15 are side cross-sectional views and plan views illustrating a method of manufacturing an image sensor according to embodiments.

### DESCRIPTION

An image sensor and a method of manufacturing the image sensor according to embodiments are described in detail with reference to the accompanying drawings. The embodiments are not limited to a CMOS image sensor and can be applied to all image sensors requiring a photodiode, including CCD image sensors.

Example FIG. 15 is a cross-sectional view showing an image sensor according to embodiments. As shown in example FIG. 15, an image sensor according to embodiments may include a wiring 150 and an interlayer dielectric layer 160 that are disposed over a first substrate 100 including a pixel part A and a periphery part B. A photodiode 200 may be disposed over the pixel part A of the first substrate 100. An upper electrode layer 260 may be connected with the photodiode 200. The first substrate 100 may be made of InSb, which is a compound semiconductor.

A method of manufacturing an image sensor according to embodiments is described hereafter with reference to example FIGS. 1 to 15. Example FIG. 1 is a schematic view of a first substrate 100 where wirings 150 are formed and example FIG. 2 is a detailed view of example FIG. 1, and the description is based on example FIG. 2.

As shown in example FIG. 1, a pixel part A and a periphery part B are defined. Wirings 150, an interlayer dielectric layer 160, and a metal layer 210 may be formed over a first substrate 100 including a readout circuit 120.

The first substrate 100 may be made of InSb, which is a compound semiconductor. The substrate 100 may be doped with p-type dopant or n-type dopant. Since the first substrate 100 is made of InSb, which is a compound semiconductor, it is possible to manufacture an infrared sensor that can sense light of a 0.78˜1000 μm wavelength. That is, it is possible to manufacture a sensor that can function as an image sensor even at night.

An active region may be defined by forming a device isolation layer over the first substrate 100. The readout circuit 120, including a transistor, may be formed in the active region. For example, the readout circuit 120 may include a transfer transistor (Tx) 121, a reset transistor (Rx) 123, a drive transistor (Dx) 125, and a select transistor (Sx) 127. An ion implantation region 130 may be formed including a floating diffusion region (FD) 131 and source/drain regions 133, 135, and 137 for the transistors. The readout circuit 120 may also assume the form of a 3 Tr structure or a 5 Tr structure.

A step of forming the readout circuit 120 over the first substrate 100 may include a step of forming an electrical junction region 140 over the first substrate 100 and a step of forming a first conductive connection region 147 connected with the wiring 150 over the electric junction region 140. For example, the electrical junction region 140 may be a PN junction, but is not limited thereto. Also, for example, the electrical junction region 140 may include a first conductive ion implantation layer 143 formed on a second conductive well 141 or a second conductive epitaxial layer, and a second conductive ion implantation layer 145 formed on the first conductive ion implantation layer 143. For example, the PN junction 140, as shown in example FIG. 2, may be a P0(145)/N-(143)/P-(141) Junction, but is not limited thereto.

According to embodiments, fully dumping a photo charge becomes possible by designing a device such that a potential difference exists between the sources/drains at both ends of the transfer transistor (Tx). Accordingly, a photo charge generated from the photodiode is dumped into the floating diffusion region, such that the sensitivity of an output image can be increased.

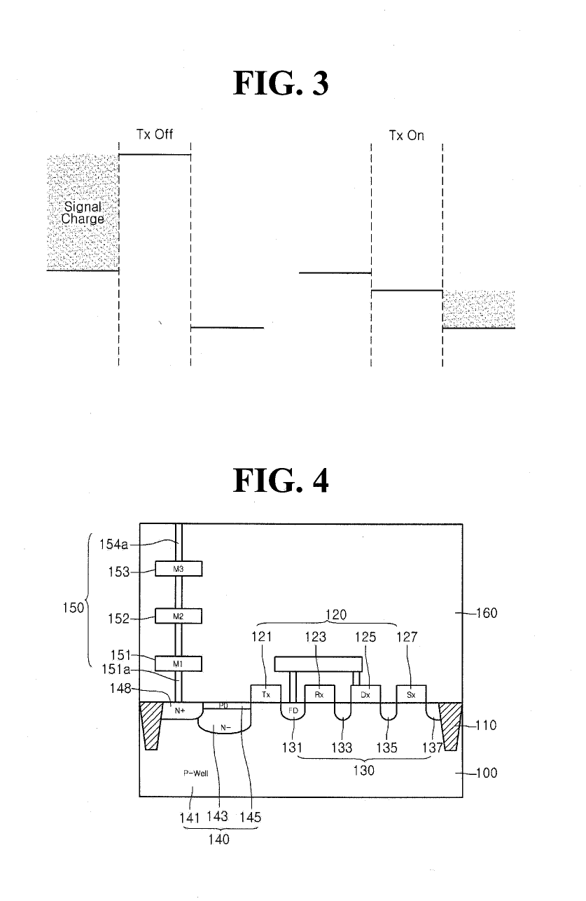

That is, it is possible to achieve full dumping of the photo charge by forming the electrical junction region 140 on the first substrate 100 with the readout circuit 120 such that a potential difference exists between the sources/drains at both ends of the transfer transistor (Tx) 121. The dumping structure of the photo charge is described hereafter in detail with reference to example FIGS. 2 and 3.

In embodiments, unlike the node of the floating diffusion (FD) 131, which is an N+ junction, the P/N/P electrical junction region 140 is not supplied with all the applied voltage, and is pinched-off at a predetermined voltage. This voltage is called the ‘pinning voltage’, which depends on the P0(145) and N-(143) doping concentrations.

In particular, electrons generated from the photodiode 205 move to the PNP junction 140, and when the transfer transistor (Tx) 121 is turned on, they are transmitted to the node of the FD 131 and converted into voltage. The maximum voltage value of the P0/N-/P-junction 140 is the pining voltage and the maximum voltage value of the node of the FD 131 is Vdd-Rx Vth. As shown in example FIG. 3, the electrons generated from the photodiode on a chip can be dumped to the node of the FD 131, without charge sharing, due to the potential difference between both ends of the Tx 131.

That is, in embodiments, the reason that the P0/N-/Pwell junction, not an N+/Pwell junction, is formed over the first InSb substrate 100, is because, in 4-Tr APS reset, positive voltage is applied to an N-143 at the P0/N-/Pwell junction and ground voltage is applied to a P0 145 and a Pwell 141, such that a P0/N-/Pwell double junction is pinched-off above a predetermined voltage, similar to a BJT structure.

Again, this is called the ‘pining voltage’. Accordingly, a potential difference is generated between the sources/drains at both ends of the Tx 121, such that the photo charge is fully dumped from the N-well to the Fd through the Tx when the Tx is turned on/off, thereby preventing charge sharing.

According to the related art image sensors, a photodiode is simply connected to an N+ junction. According to embodiments, it is possible to remove problems, such as reduction of saturation and sensitivity.

Next, according to embodiments, a first conductive connection region 147 is formed between the photodiode and the readout circuit 120 to form a passage for smooth movement of the photo charge. A dark current source is minimized, and the reduction of saturation and sensitivity can be prevented. For this purpose, according to embodiments, it is possible to form an N+ doping region as the first conductive connection region 147 for ohmic contact on the surface of the P0/N-/P-junction 140. The N+ region 147 may be formed to contact with the N-143 through the P0.

It is also possible to minimize the width of the first conductive connection region to minimize leakage in the first conductive connection region 147. For this purpose, in embodiments, a plug implant can be performed after etching a second metal contact 151a, but is not limited thereto. For example, it is possible to form an ion implantation pattern, and form the first conductive connection region 147 using the ion implantation pattern as a mask.

That is, partially applying N+ doping only to the portion where the contact is formed allows for smoothly forming an ohmic contact while minimizing a dark signal. As in the related art, when the entire Tx source is subjected to N+ doping, the dark signal may be increased by substrate surface dangling bond.

Example FIG. 4 shows another structure of a readout circuit. As shown in example FIG. 4, a first conductive connection region 148 may be formed at a side of the electrical junction region 140. The N+ connection region 148 for ohmic contact may be formed in the P0/N-/P-junction 140, in which the process of forming the N+ connection region 148 and the M1C contact 151a may be a leakage source. Because the operation is performed with reverse bias applied to the P0/N-/P-junction 140, such that an electric field may be formed on the substrate surface, a crystalline defect generated in the process of forming the contact in the electric field is a leakage source.

Further, when the N+ connection region 148 is formed on the surface of the P0/N-/P-junction 140, an electric field is added by the N+/P0 junctions 148 and 145, such that it may also be a leakage source. That is, a layout in which a first contact plug 151 a is formed at the active region formed of the N+ connection region 148, not being doped with P0 layer and it is connected with the N-junction 143. Accordingly, an electric field is not generated on the surface of the first substrate 100, which will contribute to reducing dark current of a 3-dimensional integrated CIS.

Referring to example FIG. 2 again, the wiring 150 may include a second metal contact 151a, a first metal (M1) 151, a second metal (M2) 152, and a third metal (M3) 153, but is not limited thereto. A pad 155 may be formed over the periphery part B when the third metal (M3) 153 of the wiring 150 is formed. The metal layer 210 may be formed by sequentially depositing Ti(100 Å)-TiN(220 Å)-Al(100-6000 Å).

The metal layer 210 is formed to improve bonding force with a photodiode to be bonded later, and may be made of a material that can increase the bonding force between the first substrate 100 and the photodiode. The metal layer 210 is not limited to the above material and may be made of metal, such as Al, Ti, TiN, W, Ta, TaN, Cu, Cr, Mn, Zn, Pb, Sn, and Ge, or alloys of them, Further, the metal layer 210 may be replaced by an oxide layer.

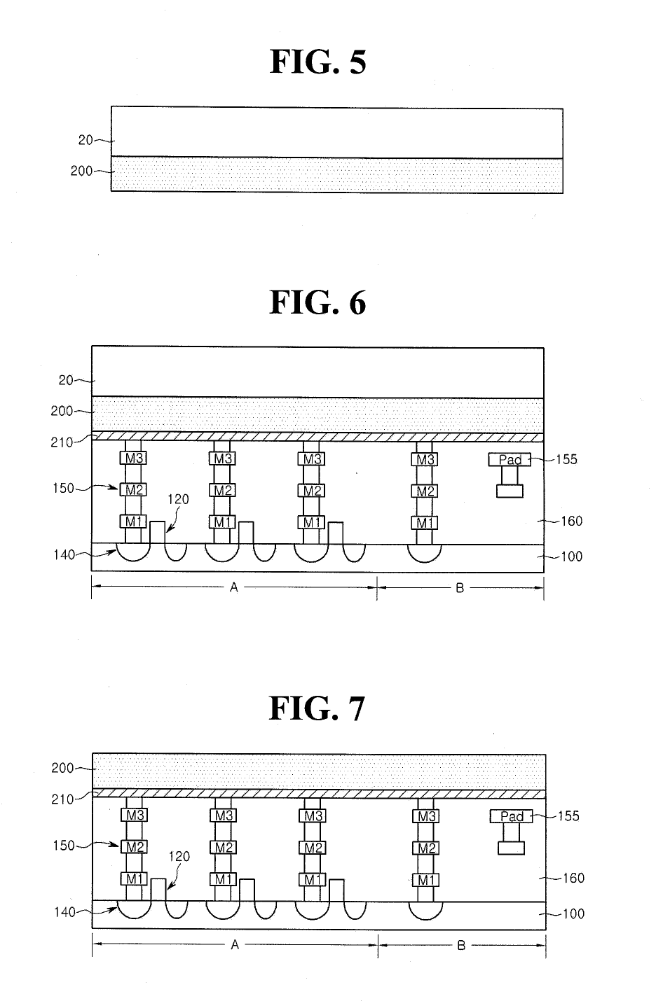

As shown in example FIG. 5, a photodiode 200 may be formed beneath a second substrate 20. The second substrate 20 is a monocrystalline or polycrystalline silicon substrate. The substrate may be doped with p-type dopant or n-type dopant. In embodiments, the second substrate 20 may be a p-type substrate. Further, the first substrate 100 and the second substrate 20 may be the same size (area). Furthermore, an epitaxial layer may be formed over the second substrate 20.

The photodiode 200 is formed inside the second substrate 20. The photodiode 200 may include an n-type dopant region and a p-type dopant region. The n-type dopant region and the p-type dopant region are formed in contact with each other so that the photodiode 200 has a PN junction.

A hydrogen ion layer may be formed between the second substrate 20 and the photodiode 200. The hydrogen ion layer is provided to separate the first substrate 20 and the photodiode 200 and may be formed by ion implantation of hydrogen ions.

Further, a metal layer may be additionally formed over the photodiode 200 to improve bonding force with the first substrate 100. The metal layer formed over the photodiode 200 may be formed by sequentially depositing TiN(220 Å)-Al(100˜6000 Å). The layer for improving the boding force with the first substrate 100 is not limited to a metal layer and it is possible to form a dielectric layer over the photodiode 200 to improve the bonding force with the first substrate 100.

Subsequently, as shown in example FIG. 6, the first substrate 100 and the second substrate 20 including the photodiode 200 are combined. The first substrate 100 and the second substrate 20 may be combined by bonding. In particular, the surface of the photodiode 200 formed beneath the second substrate 20 is placed over the metal layer 210 which is the surface of the first substrate 100, and then the first substrate 100 and the second substrate 20 are combined by bonding them. When the first substrate 100 and the second substrate 20 are combined, the metal layer 210 and the photodiode 200 are electrically connected.

As shown in example FIG. 7, the second substrate 20 may be removed, with the photodiode 200 remaining over the first substrate 100. When the second substrate 20 is removed, the photodiode 200 remains over the first substrate 100. Accordingly, the metal layer 210 and the photodiode 200 remain over the first substrate 100, such that the first substrate 100 and the photodiode 200 are vertically integrated. Since the hydrogen ion layer is formed between the second substrate 20 and the photodiode 200, the second substrate 20 and the photodiode 200 may be separated along the portion where the hydrogen ion layer is formed.

Since the first substrate 100 may be made of InSb, which is a compound semiconductor, and the photodiode 200 is formed over the first substrate 100, the photodiode 200 can sense visible light and the first substrate 100 can sense infrared light. Further, although the first substrate 100 and the photodiode 200 are combined, it may be possible to separately form and use the circuit connected with the photodiode 200 and the circuit recognizing infrared light in the first substrate 100 and generating a signal, or one circuit may be used together.

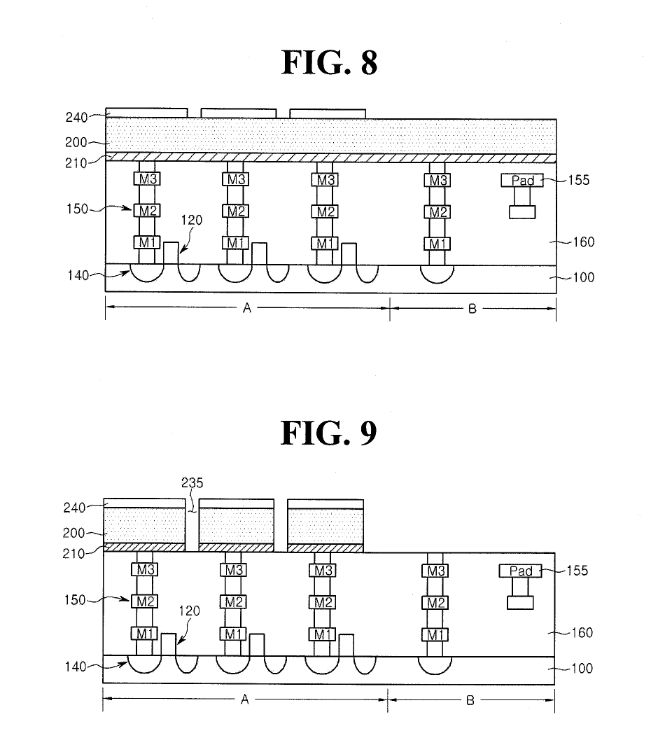

Next, as shown in example FIG. 8, a device isolation pattern 240 may be formed over the photodiode 200. The device isolation pattern 240 may be formed of a dielectric layer, such as an oxide layer, over the photodiode 200. Further, the device isolation pattern 240 selectively exposes the photodiode 200, and may be formed by patterning the dielectric layer to be divided in unit pixels. The device isolation pattern 240 may also expose the photodiode 200 on the periphery part B. The device isolation pattern 240 may be formed with a thickness of 3000 Å.

As shown in example FIG. 9, device isolation trenches 235 may be formed over the photodiode 200. The device isolation trenches 235 may be formed by etching the photodiode 200, using the device isolation pattern 240 as an etching mask. Accordingly, the photodiode 200 over the pixel part A is divided by the device isolation trenches 235 and can be connected with the wirings 150 divided in unit pixels. Further, the photodiode 200 and the metal layer 210 over the periphery part B may be removed.

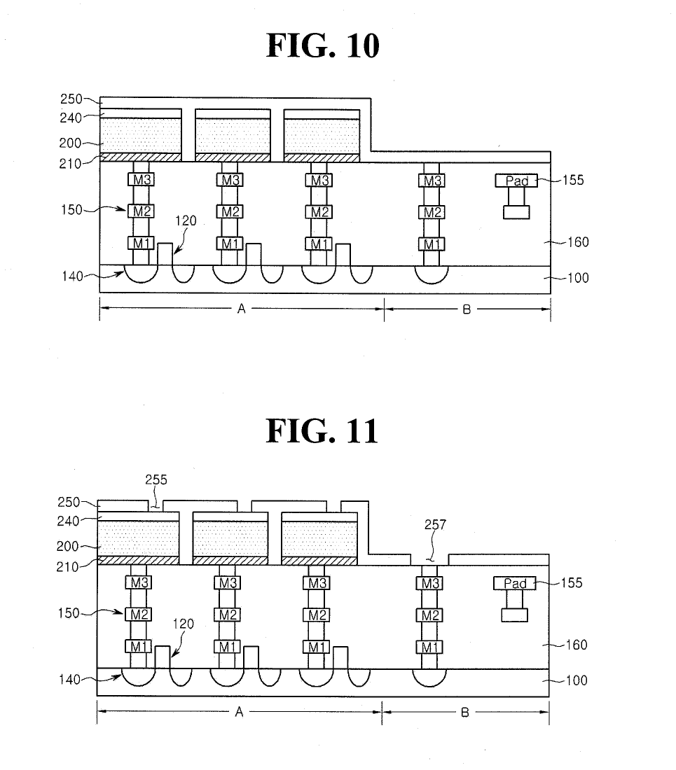

As shown in example FIG. 10, a device isolation layer 250 may be formed over the first substrate 100 including the device isolation trenches 235. The device isolation layer 250 may be formed by depositing a dielectric layer, such as an oxide layer, over the first substrate 100, with a thickness of about 4000 Å. The device isolation layer 250 may be formed over the first substrate 100 while filling the inside of the trenches 235, such that the photodiode 200 can be divided into unit pixels. It is possible to protect the devices formed over the surface of the photodiode 200 and the interlayer dielectric layer 160 over the periphery part B by forming the device isolation layer 250 throughout the upper surface of the first substrate 100.

As shown in example FIG. 11, first and second via-holes 255 and 257 may be formed in the device isolation layer 250. That is, the first via-hole 255 is formed to expose a portion of the surface of the photodiode 200 and the second via-hole 257 is formed to expose a plug connected with the wiring 150 at the periphery part B.

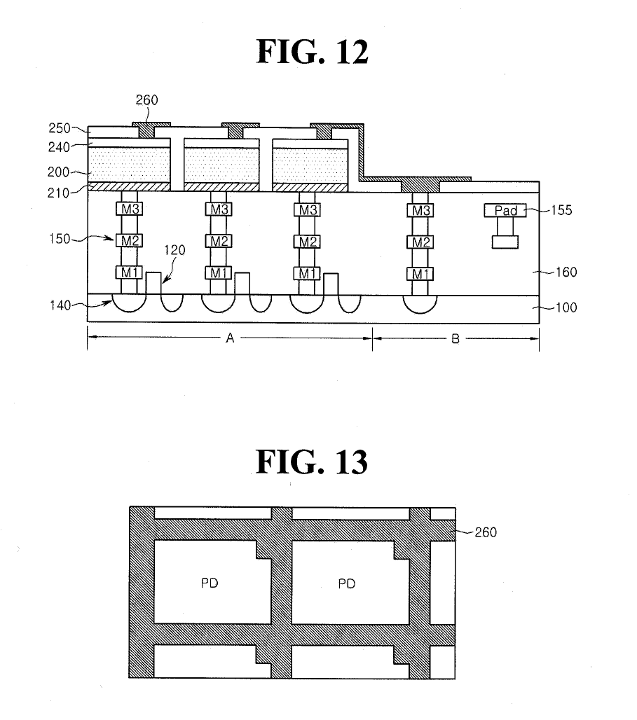

As shown in example FIG. 12, an upper electrode layer 260 may be formed over the device isolation layer 250 including the first and second via-holes 255 and 257. The upper electrode layer 260 may be formed by depositing a conductive material over the device isolation layer 250 including the first and second via-holes 255 and 257 and then patterning it.

For example, the upper electrode layer 260 may be made of a conductive material, such as titanium, aluminum, copper, cobalt, and tungsten, with a thickness of about 1000 Å. The upper electrode layer 260 may be electrically connected with the photodiode 200 through the first via-hole 255. Further, the upper electrode layer 260 may be electrically connected with the wiring 150 at the periphery part B through the second via-hole 257.

Example FIG. 13 is a plan view of an image sensor where the upper electrode layer 260 is formed, in which the upper electrode layer 260 may be formed in a mesh shape to surround the photodiode 200.

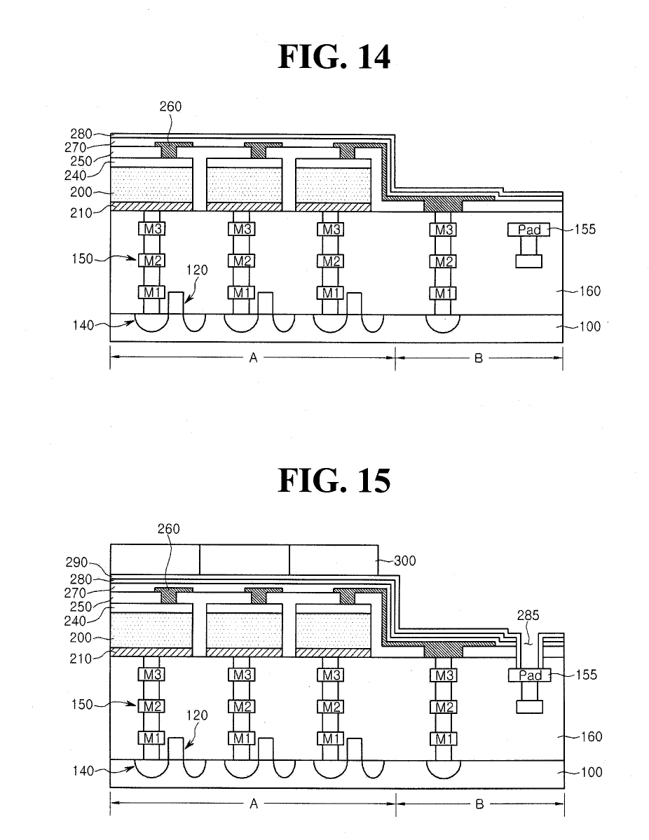

As shown in FIG. 14, a first passivation layer 270 and a second passivation layer 280 may be formed over the first substrate 100 including the upper electrode layer 260. The first passivation layer 270 may be in contact with the device isolation layer 250. For example, the first passivation layer 270 may be formed of an oxide layer or a nitride layer, with a thickness of about 1000 Å. The second passivation layer 280 may be formed over the first substrate 100 including the first passivation layer 270. For example, the second passivation layer 280 may be formed of a nitride layer or an oxide layer, with a thickness of about 1000 Å.

As shown in example FIG. 15, a pad passivation layer 290 may be formed over the first substrate 100 including the pad hole 285, which exposes the pad 155 over the periphery part B. The pad hole 285 may expose the pad 155, and may be formed by removing the interlayer dielectric layer 160, the device isolation layer 250, the first passivation layer 270, and the second passivation layer 280 over the pad 155.

After a pad passivation layer 290 is formed over the first substrate 100 including the pad hole 285, a color filter 300 may be formed over the pad passivation layer 290 at the pixel part A. One color filter 300 is formed for the unit pixel to separate colors from incident light, and can be formed in three colors of red, green, and blue.

After the color filter 300 is formed, the pad 155 can be also exposed by removing the pad passivation layer 290 formed over the pad hole 285. The pad passivation layer 290 prevents the pad 155 from being contaminated during the process of forming the color filter 300 and a microlens. The pad 155 may be exposed after the microlens is formed. Further, a planarization layer may additionally be formed over the color filter 300 before the microlens is formed, and then the microlens may be formed.

As described above, in an image sensor and a method of manufacturing the image sensor according to embodiments, crystalline silicon is formed over an interlayer dielectric layer, such that a photodiode that can sense visible light is formed. Further, since a first substrate, which is a compound semiconductor, where a lower circuit is formed, is made of InSb, it is possible to sense visible light and infrared light. Therefore, it is possible to image the shape of an object even at night. Further, it is possible to provide vertical integration of a transistor circuit and a photodiode.

It is also possible to achieve full dumping of a photo charge by designing a device such that a potential difference is generated between sources/drains at both ends of a transfer transistor (Tx). Further, according to embodiments, by forming a charge connection region between a photodiode and a readout circuit to form a path for smooth movement of a photo charge, it is possible to minimize a dark current source and prevent reduction of saturation and sensitivity.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a readout circuit formed over a first substrate made of InSb, the first substrate including a pixel part and a periphery part;
a wiring and interlayer dielectric layer that are formed over the first substrate including the readout circuit;
a photodiode formed over the interlayer dielectric layer and over the pixel part of the first substrate; and
an upper electrode layer connected with the photodiode.

2. The apparatus of claim 1, wherein the photodiode is formed by doping a crystalline silicon substrate with one of p-type dopant and n-type dopant.

3. The apparatus of claim 1, wherein the photodiode includes a device isolation layer dividing the photodiode into unit pixels.

4. The apparatus of claim 1, including an electrical junction region electrically connected with the readout circuit.

5. The apparatus of claim 4, wherein the readout circuit has a potential difference between sources and drains at both sides.

6. A method comprising:
forming a readout circuit and an interlayer dielectric layer including a wiring electrically connected with the readout circuit over a first substrate made of InSb, the first substrate including a pixel part and a periphery part;
forming a second substrate including a photodiode;
bonding the second substrate including the photodiode onto the interlayer dielectric layer;
removing the second substrate such that the photodiode remains over the interlayer dielectric layer;
forming an upper electrode layer connected with the photodiode and the wiring formed at the periphery region; and
forming a passivation layer over the upper electrode layer.

7. The method of claim 6, including:
forming a metal layer over the interlayer dielectric layer before bonding the photodiode onto the interlayer dielectric layer, wherein when the second substrate is bonded to the interlayer dielectric layer, the metal layer is disposed between the interlayer dielectric layer and the second substrate.

8. The method of claim 6, including:
forming an oxide layer over the interlayer dielectric layer before bonding the photodiode onto the interlayer dielectric layer, wherein when the second substrate is bonded to the interlayer dielectric layer, the oxide layer is disposed between the interlayer dielectric layer and the second substrate.

9. The method of claim 6, wherein the second substrate is a monocrystalline silicon substrate.

10. The method of claim 6, wherein the second substrate is a polycrystalline silicon substrate.

11. The method of claim 6, including:
forming a device isolation layer over the photodiode such that the photodiode is divided into unit pixels.

12. The method of claim 11, wherein the device isolation layer is formed by forming a device isolation trench in the photodiode, and depositing a dielectric layer into the device isolation trench and over the photodiode.

13. The method of claim 12, wherein, when the device isolation trench is formed, the photodiode over the periphery part is removed and the wiring at the periphery part is exposed.

14. The method of claim 6, wherein forming a passivation layer over the upper electrode layer includes forming a first passivation layer, and a second passivation layer over the first passivation layer.

15. The method of claim 14, including forming a pad passivation layer over the second passivation layer.

16. The method of claim 13, including forming a color filter layer over the pad passivation layer.

17. The method of claim 16, wherein the color filter layer includes red, green and blue color filters.

18. The method of claim 17, including forming a via through the pad passivation layer after forming the color filter layer.

19. The method of claim 6, including forming an electrical junction region electrically connected with the readout circuit.

20. The method of claim 19, wherein the readout circuit has a potential difference between sources and drains at both ends of a transistor.
